(19) United States
(12) Patent Application Publication
(10) Pub. No.: US 2025/0308765 A1
(43) Pub. Date: Oct. 2, 2025

(54) LOOPBACK CIRCUIT PACKAGE AND MANUFACTURING METHOD THEREOF

(71) Applicant: ELSPES INC., Daejeon (KR)

(72) Inventors: Taedong KIM, Hwaseong-si (KR); Wisnu MURTI, Hwaseong-si (KR); Seunggu LIM, Hwaseong-si (KR); Yeongyeol PARK, Yongin-si (KR); Heeil CHAE, Hwaseong-si (KR)

(21) Appl. No.: 18/793,435

(22) Filed: Aug. 2, 2024

(30) Foreign Application Priority Data
Mar. 29, 2024 (KR) 10-2024-0043526

(51) Int. Cl. H01F 27/40; H01F 27/28; H03H 7/00

(52) U.S. Cl. CPC H01F 27/40; H01F 27/2804; H03H 7/00

(57) ABSTRACT

A loopback circuit package comprises an inductor layer and a semiconductor substrate. The inductor layer includes a first inductor, a second inductor, a third inductor, and a fourth inductor, and. The semiconductor substrate includes a first capacitor electrically connected to the first inductor and the second inductor, and a second capacitor electrically connected to the third inductor and the fourth inductor. The first capacitor and the second capacitor are disposed in a first recess and a second recess of the semiconductor substrate, respectively.

### CROSS-REFERENCE TO RELATED APPLICATION

This application claims priority to Korean Patent Application No. 10-2024-0043526, titled LOOPBACK CIRCUIT PACKAGE AND MANUFACTURING METHOD THEREOF, filed in the Korean Intellectual Property Office on Mar. 29, 2024, which is hereby incorporated by reference in its entireties

### TECHNICAL FIELD

This application has been conducted by the support of Ministry of SMEs and Startups of Republic of Korea. Research title is “SME technology innovation development project”, and the subject identification number is RS-2023-00285252.

Embodiments of the present disclosure relate to a loopback circuit package and a manufacturing method thereof. More specifically, embodiments of the present disclosure relate to a loopback circuit package employed in a test apparatus for automated testing of integrated circuits and a manufacturing method thereof.

### BACKGROUND

Recently, high-performance System-on-Chip (SOC) devices have been utilized in applications such as smartphones, artificial intelligence, autonomous vehicles, and the Internet of Things (IoT). In a relatively high-frequency domain, technologies to reduce power noise, switching noise, and the like have been developed. With the integration of more precise electronic components into recent high-performance chips, and as their sizes decrease and performance improves, precise testing to ensure these components are properly integrated and functioning is desirable.

Semiconductor devices, integrated circuits, and electronic components such as printed circuit board (PCB) assemblies may be frequently tested by testing devices during or after manufacturing to ensure quality and reliability. Among such testing devices, loopback circuits may be employed in various testing devices (e.g., automated testing devices).

Conventional loopback circuits may include passive components such as inductors and capacitors, which can cause issues including signal loss of relatively high-frequency signals and relatively large overall thickness.

### SUMMARY

A lookback circuit package according to various embodiments of the present disclosure can be described as follows.

According to an embodiment of the present disclosure, a loopback circuit package includes an inductor layer including a first inductor, a second inductor, a third inductor, and a fourth inductor; and a semiconductor substrate including a first capacitor electrically connected to the first inductor and the second inductor and a second capacitor electrically connected to the third inductor and the fourth inductor. The first capacitor and the second capacitor are disposed in a first recess and a second recess of the semiconductor substrate, respectively.

In an embodiment of the present disclosure, the loopback circuit package may further include first signal transmission portions electrically connected to the first inductor, the second inductor, and the first capacitor, second signal transmission portions electrically connected to the third inductor, the fourth inductor, and the second capacitor, and shock mitigation portions arranged between the semiconductor substrate and the first inductor, the second inductor, the third inductor, and the fourth inductor.

According to an embodiment of the present disclosure, the loopback circuit package may include a first LC section comprising the first inductor, the second inductor, and the first capacitor, and a second LC section comprising the third inductor, the fourth inductor, and the second capacitor.

In an embodiment of the present disclosure, the first inductor of the first LC section and the third inductor of the second LC section are spaced apart from each other, or the second inductor of the first LC section and the fourth inductor of the second LC section are spaced apart from each other, or both. An air gap or a molding layer is formed between the first inductor the third inductor, or between the second inductor and the fourth inductor, or both.

According to an embodiment of the present disclosure, the loopback circuit package may further include a package substrate. The inductor layer is disposed on an upper surface of the package substrate, the semiconductor substrate is disposed on an upper surface of the inductor layer, and the first and second signal transmission portions and the shock mitigation portions are disposed between the inductor layer and the semiconductor substrate.

In an embodiment of the present disclosure, the first recess and the second recess may be formed on a lower surface of the semiconductor substrate.

According to an embodiment of the present disclosure, the first signal transmission portions comprise a first signal pad configured to transmit a signal and disposed to contact the first inductor and the first capacitor and a second signal pad configured to transmit a signal and disposed to contact the second inductor and the first capacitor. The second signal transmission portions comprise a third signal pad configured to transmit a signal and disposed to contact the third inductor and the second capacitor and a fourth signal pad configured to transmit a signal and disposed to contact the fourth inductor and the second capacitor.

In an embodiment of the present disclosure, the shock mitigation portions may include: a first dummy pad disposed to contact the first inductor and the semiconductor substrate; a second dummy pad disposed to contact the second inductor and the semiconductor substrate; a third dummy pad disposed to contact the third inductor and the semiconductor substrate; and a fourth dummy pad disposed to contact the fourth inductor and the semiconductor substrate.

According to an embodiment of the present disclosure, the first signal pad, the second signal pad, the third signal pad, and the fourth signal pad further reduce impedance mismatch between the first inductor and the first capacitor, between the second inductor and the first capacitor, between the third inductor and the second capacitor, and between the fourth inductor and the second capacitor, respectively.

In an embodiment of the present disclosure, the loopback circuit package may further include connection pads arranged between the package substrate and the inductor layer.

In an embodiment of the present disclosure, the inductor layer is disposed on an upper surface of the semiconductor substrate, and the first and second signal transmission portions and the shock mitigation portions are arranged between the inductor layer and the semiconductor substrate.

In an embodiment of the present disclosure, the first and second recesses may be formed on an upper surface of the semiconductor substrate.

In an embodiment of the present disclosure, the first signal transmission portions include: a first signal bump disposed to contact the first inductor and the first capacitor to transmit a signal; a second signal bump disposed to contact the second inductor and the first capacitor to transmit a signal. The second signal transmission portions include a third signal bump disposed to contact the third inductor and the second capacitor to transmit a signal; and a fourth signal bump disposed to contact the fourth inductor and the second capacitor to transmit a signal.

In an embodiment of the present disclosure, the shock mitigation portions may include: a first dummy bump disposed to contact the first inductor and the semiconductor substrate; a second dummy bump disposed to contact the second inductor and the semiconductor substrate; a third dummy bump disposed to contact the third inductor and the semiconductor substrate; and a fourth dummy bump disposed to contact the fourth inductor and the semiconductor substrate.

In an embodiment of the present disclosure, the loopback circuit package further comprises a package substrate on which the inductor layer is disposed. One or more substrate grooves may be formed on an upper surface of the package substrate, and the substrate grooves may have a size and a thickness corresponding to those of the semiconductor substrate.

In an embodiment of the present disclosure, the semiconductor substrate may be placed in the substrate grooves of the package substrate, and the inductor layer may be disposed on an upper surface of the semiconductor substrate, and the first and second signal transmission portions and the shock mitigation portions may be arranged between the inductor layer and the semiconductor substrate.

In an embodiment of the present disclosure, a method of manufacturing a loopback circuit package includes providing a package substrate, providing an inductor layer on the package substrate, the inductor layer including a first inductor, a second inductor, a third inductor, and a fourth inductor, and providing a semiconductor substrate on the package substrate, the semiconductor substrate including a first capacitor electrically connected to the first inductor and the second inductor and a second capacitor electrically connected to the third inductor and the fourth inductor. The first capacitor and the second capacitor are disposed in a first recess and a second recess of the semiconductor substrate, respectively, and the first recess and the second recess are formed by etching the semiconductor substrate.

Embodiments of the present disclosure may reduce an overall thickness of a loopback circuit package by forming deep trench-shaped capacitors in recesses formed on the semiconductor substrate, after forming the recesses on the semiconductor substrate to secure sufficient capacitance.

Embodiments of the present disclosure can minimize the loss of high-frequency signals by arranging signal pads to overlap with capacitors on the semiconductor substrate and by arranging one or more dummy pads to at least partially overlap with capacitors.

Embodiments of the present disclosure can ensure stable placement of the semiconductor substrate on the inductor layer even under external shocks by arranging one or more dummy pads between the semiconductor substrate and the inductor layer.

Beneficial aspects obtainable from embodiments of the present disclosure are not limited to those mentioned above, and other beneficial aspects may be understood by those skilled in the art in the relevant technical field from the teachings of the following disclosure.

### BRIEF DESCRIPTION OF DRAWINGS

FIG. 1 is a circuit diagram illustrating a loopback circuit according to an embodiment of the present disclosure.

FIG. 2 is a schematic plan view of a loopback circuit package according to an embodiment of the present disclosure.

FIG. 3 is a schematic cross-sectional view taken along line III-III′ of FIG. 2.

FIG. 4 is an exploded cross-sectional view of FIG. 3.

FIG. 5 is a schematic cross-sectional view illustrating a semiconductor substrate and a capacitor structure therein, according to an embodiment of the present disclosure.

FIG. 6 is a flowchart illustrating a manufacturing method of a loopback circuit package according to an embodiment of the present disclosure.

FIG. 7 is a schematic plan view of a loopback circuit package according to an embodiment of the present disclosure.

FIG. 8 is a schematic cross-sectional view taken along line VIII-VIII′ of FIG. 7.

FIG. 9 is a flowchart illustrating a manufacturing method of a loopback circuit package according to an embodiment of the present disclosure.

FIG. 10 is a schematic sectional view of a loopback circuit package according to an embodiment of the present disclosure.

### DESCRIPTION OF EMBODIMENTS

Detailed descriptions of embodiments are provided below along with accompanying figures. The scope of this disclosure is limited by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

The shapes, sizes, proportions, angles, quantities, etc., disclosed in the drawings for explaining embodiments of the present disclosure are merely examples. When terms such as “includes,” “has,” “comprises,” etc., are used in this specification, unless “only” is explicitly used, additional elements may be included.

In descriptions of positional relationships, for example, when the positional relationship between two parts is described as “on,” “above,” “below,” “next to,” etc., without using “directly” or “immediately,” one or more other parts may be positioned between the two parts.

Although terms such as “first,” “second,” etc., are used to describe various components, and these terms are merely used to distinguish one component from another.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

Hereinafter, various embodiments of the present disclosure will be described in detail with reference to the accompanying drawings.

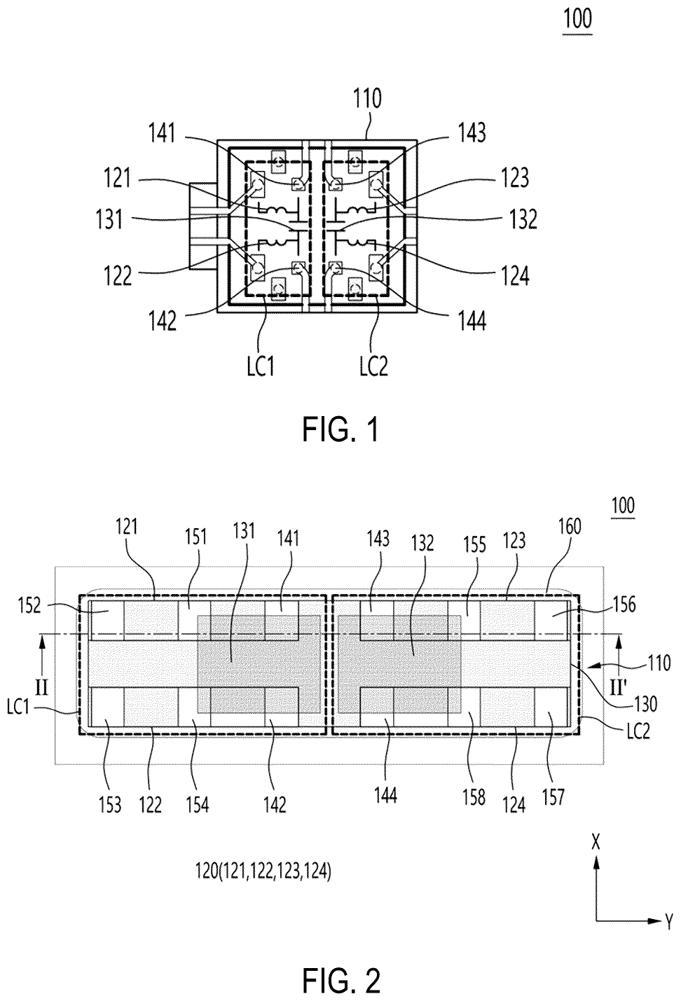

FIG. 1 is a circuit diagram illustrating a loopback circuit according to an embodiment of the present disclosure.

Referring to FIG. 1, the loopback circuit (100) according to an embodiment of the present invention includes a first LC section (LC1) arranged on one side of the package substrate (110) and a second LC section (LC2) arranged on the other side of the package substrate (110) and spaced apart from the first LC section (LC1). The first LC section (LC1) and the second LC section (LC2) can be flip arranged with respect to the center on the package substrate (110). For example, the first LC section (LC1) and the second LC section (LC2) may be substantially symmetrically arranged with respect to the center line of the package substrate (110) when seen in a plan view.

The first LC section (LC1) may include a first inductor (121), a second inductor (122), a first capacitor (131), a first signal pad (141), and a second signal pad (142). The first signal pad (141) and the second signal pad (142) may be referred to as first signal transmission portions. In addition, the first signal pad (141) and the second signal pad (142) may reduce impedance mismatch between the first inductor (121) and the first capacitor (131) and between the second inductor (122) and the first capacitor (131), respectively.

The first inductor (121) and the second inductor (122) are disposed on the package substrate (110) and spaced apart from each other, and the first capacitor (131) is positioned between the first inductor (121) and the second inductor (122). A first electrode (or a first end) of the first capacitor (131) is electrically connected to the first inductor (121), and a second electrode (or a second end) of the first capacitor (131) is electrically connected to the second inductor (122). The first capacitor (131) may be a Multi-Layer Ceramic Capacitor (MLCC) or a trench capacitor having a trench structure, for large-capacity implementation.

The first signal pad (141) and the second signal pad (142) each transmit electrical signals to the first inductor (121), the second inductor (122), and the first capacitor (131). Specifically, the first signal pad (141) and the second signal pad (142) may transmit sink signals and/or source signals to the first inductor (121), the second inductor (122), and the first capacitor (131).

The second LC section (LC2) may include a third inductor (123), a fourth inductor (124), a second capacitor (132), a third signal pad (143), and a fourth signal pad (144). The third signal pad (143) and the fourth signal pad (144) may be referred to as second signal transmission portions. In addition, the third signal pad (143) and the fourth signal pad (144) may reduce impedance mismatch between the third inductor (123) and the second capacitor (132) and between the fourth inductor (124) and the second capacitor (132), respectively.

The third inductor (123) and the fourth inductor (124) are disposed on the package substrate (110) and spaced apart from each other, and the second capacitor (132) is positioned between the third inductor (123) and the fourth inductor (124). A first electrode of the second capacitor (132) is electrically connected to the third inductor (123), and a second electrode of the second capacitor (132) is electrically connected to the fourth inductor (124). The second capacitor (132) may be an MLCC or a trench capacitor having a trench structure, and be implemented as substantially the same capacitor as the first capacitor (131).

The third signal pad (143) and the fourth signal pad (144) each transmit electrical signals to the third inductor (123), the fourth inductor (124), and the second capacitor (132). Specifically, the third signal pad (143) and the fourth signal pad (144) may transmit sink signals and/or source signals to the third inductor (123), the fourth inductor (124), and the second capacitor (132).

When a loopback circuit includes conventional MLCC-type capacitors for large-capacity implementation, since the conventional MLCC-type capacitors may be relatively thick, an overall thickness of such a loopback circuit may be excessively increased. In contrast, a loopback circuit (100) according to embodiments of the present disclosure, which includes MLCC-type first capacitor (131) and second capacitor (132) for large-capacity implementation, as will be described below in more detail, may have a structure that significantly reduces its overall thickness, compared to when conventional MLCC-type capacitors are included therein.

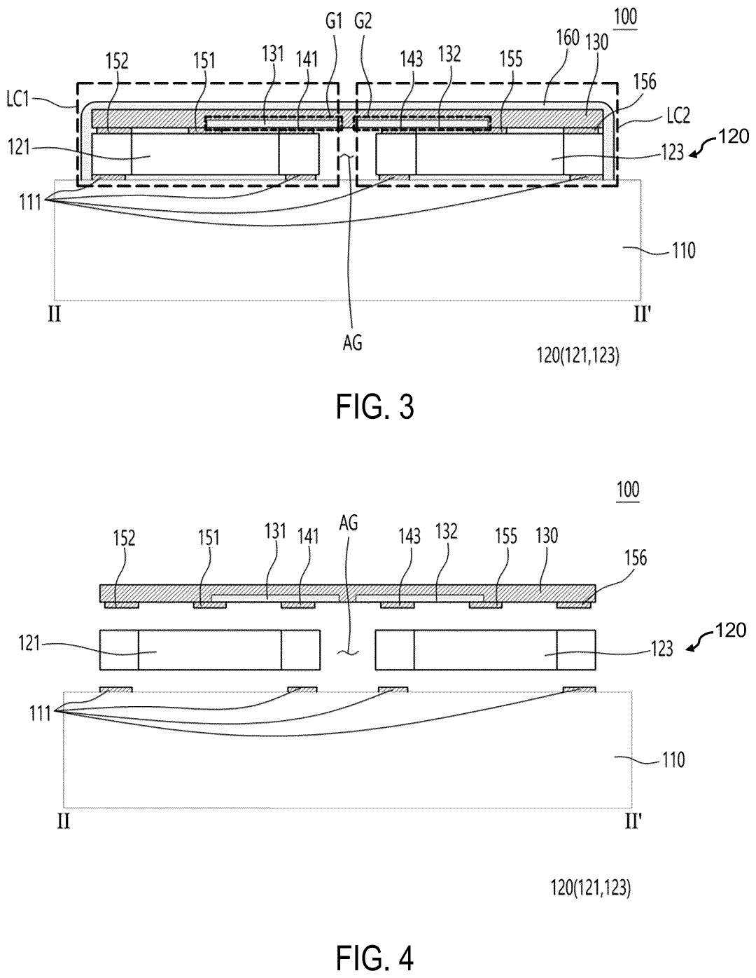

FIG. 2 is a schematic plan view of a loopback circuit package according to an embodiment of the present disclosure, FIG. 3 is a schematic cross-sectional view taken along line III-III′ of FIG. 2, and FIG. 4 is an exploded cross-sectional view of FIG. 3.

Referring to FIGS. 2 to 4, the loopback circuit package (100) according to an embodiment of the present disclosure may include an inductor layer (120) disposed on the package substrate (110) and a semiconductor substrate (130) disposed on the inductor layer (120). Referring to FIG. 2, the inductor layer (120) and the semiconductor substrate (130) of the loopback circuit package (100) occupy a smaller area than the package substrate (110).

The package substrate (110) may serve as a support board for the loopback circuit package (100). Multiple connection pads (111) for connection with the inductor layer (120) are arranged on the upper surface of the package substrate (110). The package substrate (110) may be composed of materials such as ceramic, silicon, build-up layers, or any other suitable material.

The inductor layer (120) may be positioned between the package substrate (110) and the semiconductor substrate (130). The inductor layer (120) may include the first inductor (121) and the second inductor (122) of the first LC section (LC1), and the third inductor (123) and the fourth inductor (124) of the second LC section (LC2). As shown in FIGS. 2 and 3, the first inductor (121) of the first LC section (LC1) and the third inductor (123) of the second LC section (LC2) are spaced apart from each other with a separation. An air gap (AG) or a portion of a mold layer (160) may be disposed between the first inductor (121) of the first LC section (LC1) and the third inductor (123) of the second LC section (LC2). Thus, the loopback circuit package (100) according to an embodiment of the present disclosure can clearly separate the first LC section (LC1) and the second LC section (LC2). Furthermore, with the clear separation implemented by the air gap (AG) or the mold layer (160), the integration density may be increased by including two independent LC circuits within a single loopback circuit package.

Each of the first inductor (121) and the second inductor (122) can be electrically connected to the first capacitor (131) that is disposed on upper surfaces of the first and second inductors (121) and (122). Specifically, the first inductor (121) can be connected to the first electrode of the first capacitor (131), and the second inductor (122) can be connected to the second electrode of the first capacitor (131).

Each of the third inductor (123) and the fourth inductor (124) can be electrically connected to the second capacitor (132) that is disposed on upper surfaces of the third and fourth inductors (123) and (124). Specifically, the third inductor (123) can be connected to the first electrode of the second capacitor (132), and the fourth inductor (124) can be connected to the second electrode of the second capacitor (132). The first inductor (121) through the fourth inductor (124) may be, for example, magnetic inductors or magnetic core inductors.

Referring to FIGS. 2 to 4, the semiconductor substrate (130) is positioned above the inductor layer (120). The semiconductor substrate (130) may be composed of silicon material, more specifically, silicon material of any one of P-type, N-type, and undoped.

On a lower surface of the semiconductor substrate (130), first trench (or first recess) (G1) and second trench (or second recess) (G2) are formed. The first trench (G1) and second trench (G2) may be formed on a lower surface of the semiconductor substrate (130) by etching a lower portion of the semiconductor substrate (130). The first trench (G1) can be formed in a region overlapping with the first inductor (121) and the second inductor (122), while the second trench (G2) can be formed in a region overlapping with the third inductor (123) and the fourth inductor (124).

The first capacitor (131) may be disposed in the first trench (or first recess) (G1), and the second capacitor (132) may be disposed in the second trench (or second recess) (G2). Thus, the first capacitor (131) can be partially overlapped with the first inductor (121) and the second inductor (122), while the second capacitor (132) can be partially overlapped with the third inductor (123) and the fourth inductor (124). Accordingly, in an embodiment of the present disclosure, the loopback circuit package (100) can address the issue of increased overall thickness in a conventional loopback circuit by etching a portion of the semiconductor substrate (130) to arrange the first capacitor (131) in the first trench (G1) and the second capacitor (132) in the second trench (G2). The first capacitor (131) and the second capacitor (132) each may have a trench structure to form a relatively thin capacitor in the first trench (G1) or the second trench (G2).

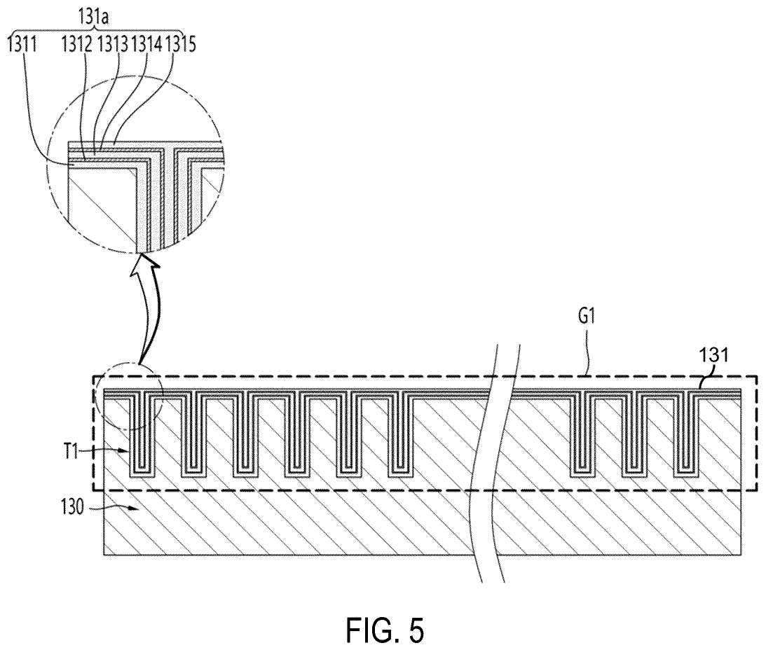

The first capacitor (131) and the second capacitor (132) can have substantially the same form. Specifically, each of the first capacitor (131) and the second capacitor (132) can be a trench-type capacitor with a trench structure capable of providing sufficient capacitance, namely, a deep trench capacitor. More detailed structures of the first capacitor (131) and the second capacitor (132) will be described in detail by referring to the following FIG. 5.

When the semiconductor substrate (130) includes the first capacitor (131) and the second capacitor (132), first to fourth signal pads (141, 142, 143, 144) and first to eighth dummy pads (151, 152, 153, 154, 155, 156, 157, 158) may be disposed between the semiconductor substrate (130) and the inductor layer (120). The first LC section (LC1) may additionally include the first to fourth dummy pads (151, 152, 153, 154), while the second LC section (LC2) may additionally include the fifth to eighth dummy pads (155, 156, 157, 158).

The first capacitor (131) can be electrically connected to the first inductor (121) by the first signal pad (141) and to the second inductor (122) by the second signal pad (142). The first signal pad (141) and the second signal pad (142) can serve as source pads and/or sink pads for transmitting source signals and/or sink signals to the first capacitor (131), the first inductor (121), and the second inductor (122).

The second capacitor (132) can be electrically connected to the third inductor (123) by the third signal pad (143) and to the fourth inductor (124) by the fourth signal pad (144). The third signal pad (143) and the fourth signal pad (144) can serve as source pads and/or sink pads for transmitting source signals and/or sink signals to the second capacitor (132), the third inductor (123), and the fourth inductor (124).

The first dummy pad (151) can be arranged between the first capacitor (131) and the first inductor (121) to be in contact with each of the first capacitor (131) and the first inductor (121). The second dummy pad (152) can be arranged between the bottom surface of the semiconductor substrate (130) and the first inductor (121) to be in contact with the bottom surface of the semiconductor substrate (130) and the first inductor (121). In an embodiment, the first dummy pad (151) may be disposed between the first inductor (121) and the first capacitor (131) to partially overlap the first capacitor (131). For example, an area of the first dummy pad (151) overlapping the first capacitor (131) may be in a range about 10% to about 50% of the total area of the first dummy pad (151). Additionally, the second dummy pad (152) ensures stable placement of the semiconductor substrate (130) and the first capacitor (131) on the first inductor (121) even under external shocks. Specifically, the second dummy pad (152) may include one or more materials and have dimensions suitable for absorbing and dissipating external shock energy. For example, the second dummy pad (152) may include the same material(s) as the first dummy pad (151) and have a size sufficient to support the first capacitor (131) placed over the first inductor (121).

The third dummy pad (153) can be positioned between the bottom surface of the semiconductor substrate (130) and the second inductor (122) to be in contact with both the bottom surface of the semiconductor substrate (130) and the second inductor (122). The fourth dummy pad (154) can be arranged between the first capacitor (131) and the second inductor (122) to be in contact with each of the first capacitor (131) and the second inductor (122). The third dummy pad (153) ensures stable placement of the semiconductor substrate (130) and the first capacitor (131) on the second inductor (122) even under external shocks.

The fifth dummy pad (155) can be positioned between the second capacitor (132) and the third inductor (123) to be in contact with both the second capacitor (132) and the third inductor (123). The sixth dummy pad (156) can be arranged between the bottom surface of the semiconductor substrate (130) and the third inductor (123) to be in contact with both the bottom surface of the semiconductor substrate (130) and the third inductor (123). Additionally, the sixth dummy pad (156) ensures stable placement of the semiconductor substrate (130) and the second capacitor (132) on the third inductor (123) even under external shocks.

The seventh dummy pad (157) can be positioned between the bottom surface of the semiconductor substrate (130) and the fourth inductor (124) to be in contact with both the bottom surface of the semiconductor substrate (130) and the fourth inductor (124). The eighth dummy pad (158) can be arranged between the second capacitor (132) and the fourth inductor (124) to be in contact with both the second capacitor (132) and the fourth inductor (124). The seventh dummy pad (157) ensures stable placement of the semiconductor substrate (130) and the second capacitor (132) on the fourth inductor (124) even under external shocks.

Therefore, the second dummy pad (152), the third dummy pad (153), the sixth dummy pad (156), and the seventh dummy pad (157) can be referred to as shock mitigation portions.

The mold layer (160) is placed to cover (e.g., encapsulate or encase) both the inductor layer (120) disposed on the upper surface of the package substrate (110) and the semiconductor substrate (130) disposed on the upper surface of the inductor layer (120). The mold layer (160) can wrap around substantially the entire sides of the inductor layer (120) and the semiconductor substrate (130), as well as their upper surfaces. The mold layer (160) can be composed of materials such as epoxy resin or various other encapsulating materials and substances.

Next, by referring to FIG. 5, a capacitor structure that can be used in embodiments of the present disclosure will be described in detail. For example, these embodiments each may include the first capacitor (131) the second capacitor (132) positioned on the semiconductor substrate (130).

FIG. 5 is a cross-sectional view illustrating a capacitor structure of a loopback circuit package (e.g., the loopback circuit package 100 in FIGS. 2-4) according to an embodiment of the present disclosure. Since the first capacitor (131) and the second capacitor (132) have substantially the same structure, only the first capacitor (131) will be describe for the interest of simplicity. FIG. 5 depicts the first capacitor (131) facing upwards for illustration purposes, which is obtained by inverting the semiconductor substrate (130) including the first capacitor (131) in FIGS. 2 to 4.

Referring to FIG. 5, the first capacitor (131) may include a first capacitor pattern (131a) formed in an area of the first trench (G1) on an upper surface of the inverted semiconductor substrate (130) (or the lower surface of the semiconductor substrate (130) in FIGS. 2 to 4). Additionally, the first trench (G1) may consist of multiple first trenches (T1). Thus, the first capacitor pattern (131a) may be formed along multiple first trenches (T1) within the region of the first trench (G1) on the semiconductor substrate (130). Each of the multiple first trenches (T1) may be formed at an angle of approximately 90 degree angle with respect to a main surface (e.g., the upper surface) of the semiconductor substrate (130). For example, each of the first trenches (T1) may extend in a direction substantially orthogonal to the main surface of the semiconductor substrate (130). Each of the multiple first trenches (T1) may be a deep trench formed with a aspect ratio of 10:1 or higher, having a given depth, for example, ranging from 1 μm to 20 μm. Additionally, the multiple first trenches (T1) may be spaced apart from each other at a given interval (e.g., a predetermined interval), for example, ranging from 0.1 μm to 1 μm. For example, two facing sidewalls of an adjacent pair of the first trenches may be spaced apart from each other at a predetermined interval (e.g., from 0.1 μm to 1 μm).

The first capacitor pattern (131a) may include capacitor electrode layers (1311, 1313, 1315) and dielectric layers (1312, 1314) alternately formed along multiple first trenches (T1) on the upper surface of the semiconductor substrate (130). In the embodiment of FIG. 5, the first capacitor pattern (131a) is illustrated as including three capacitor electrode layers (1311, 1313, 1315) and two dielectric layers (1312, 1314), but embodiments of the present disclosure are not limited thereto and the numbers of capacitor electrode layers and dielectric layers can be appropriately selected according to design specifications.

The capacitor electrode layers (1311, 1313, 1315) can be formed from one or more conductive materials such as Tungsten (W), Titanium Nitride (TiN), Platinum (Pt), Aluminum (Al), Ruthenium (Ru), Doped/Poly-silicon (Doped.Poly-Si), or a combination thereof. The materials of these capacitor electrode layers are not limited to the examples listed and can be composed of various conductive materials. The dielectric layers (1312, 1314) can be formed from one or more dielectric materials including SiO, SiN, AlO, TiO, HfO, ZrO, STO, or other high-K materials. Preferably, the dielectric layers (1312, 1314) can be composed of SiO2, Si3N4, Al2O3, TiO2, HfO2, ZrO2, RuO2, but the materials of these capacitor dielectric layers are not limited to the examples listed, and various dielectric materials can be used.

In FIG. 5, the first capacitor (131) has a single layer deep trench capacitor structure in which multiple first trenches (T1) are formed in a single semiconductor substrate (130). For example, the first capacitor (131) is formed in the area of the first trench (G1) on the lower surface of the single semiconductor substrate (130). According to various embodiments of the present disclosure, the first capacitor (131) can include a deep trench capacitor structure formed along trenches formed in two or more semiconductor substrates. For example, the first capacitor (131) can be formed in the area of the first trench (G1) of the two or more semiconductor substrates (130). Thus, the first capacitor (131) can have a multilayer deep trench capacitor structure stacked in the area of the first trench (G1).

Thus, according to embodiments of the present disclosure, the loopback circuit package (100) forms the first capacitor (131) and the second capacitor (132) on the semiconductor substrate (130) in the form of deep trench capacitors, thereby minimizing the size and thickness of the loopback circuit package while increasing the capacitance compared to conventional methods.

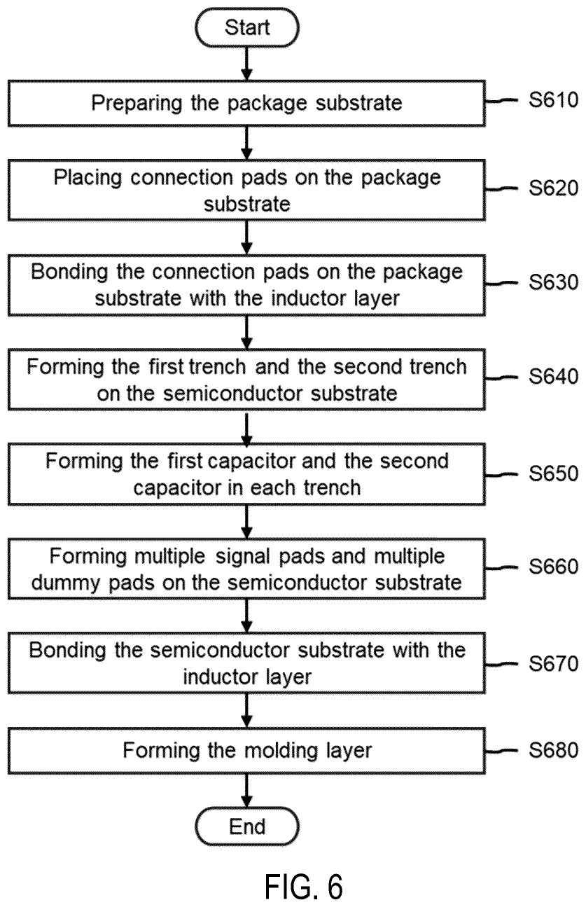

A manufacturing process of a loopback circuit package (e.g., the loopback circuit package (100) in FIGS. 2-4) according to an embodiment of the present disclosure will be described below with reference to FIG. 6.

FIG. 6 is a flowchart illustrating the manufacturing method of the loopback circuit package (100) according to an embodiment of the present disclosure.

Referring to FIG. 6, the method of manufacturing the loopback circuit package (100) includes preparing the package substrate (110) (S610), then placing connection pads (111) on the package substrate (110) (S620), and bonding the connection pads (111) on the package substrate (110) with the inductor layer (120) comprising the first inductor (121) and the second inductor (122) (S630).

Subsequently, after preparing the semiconductor substrate (130), the method includes forming the first trench (or the first recess) (G1) and the second trench (or the second recess) (G2) on the semiconductor substrate (130) (S640), and forming the first capacitor (131) and the second capacitor (132) in respective trenches (G1 and G2) (S650). After forming multiple trenches in each of the respective trenches (G1 and G2) for the first capacitor (131) and the second capacitor (132), the first capacitor pattern (131a) and the second capacitor pattern are formed along the multiple trenches to create the first capacitor (131) and the second capacitor (132) in the first and second trenches (G1 and G2), respectively.

Next, on the semiconductor substrate (130) where the first capacitor (131) and the second capacitor (132) are formed, multiple signal pads, namely, the first signal pad (141), the second signal pad (142), the third signal pad (143), and the fourth signal pad (144), are formed to overlap with the first capacitor (131) and the second capacitor (132), and multiple dummy pads, namely, at least some of the first to eighth dummy pads (151, 152, 153, 154, 155, 156, 157, 158), each are formed to overlap with one or both of the first capacitor (131) and the second capacitor (132) (S660).

The first to fourth signal pads (141, 142, 143, 144) and the first to eighth dummy pads (151, 152, 153, 154, 155, 156, 157, 158) are then bonded to the inductor layer (120) by facing the inductor layer (120) (S670).

Afterwards, a molding layer (160) is formed to cover (e.g., encapsulate) substantially the entire sides of the inductor layer (120) as well as substantially the entire sides and a top surface of the semiconductor substrate (130) on the package substrate (110) (S680). While in the embodiment of FIG. 6, the process of forming the first and second capacitors (131, 132) on the semiconductor substrate (130) is performed after placing the inductor layer (120) on the package substrate (110), embodiments of the present disclosure are not limited thereto. For example, in other embodiments, the first and second capacitors (131, 132) on the semiconductor substrate (130) may be formed first. Additionally, the inductor layer (120) may be formed on the package substrate (110) after the capacitors (131, 132) are formed, and the semiconductor substrate (130) may be formed on the inductor layer (120).

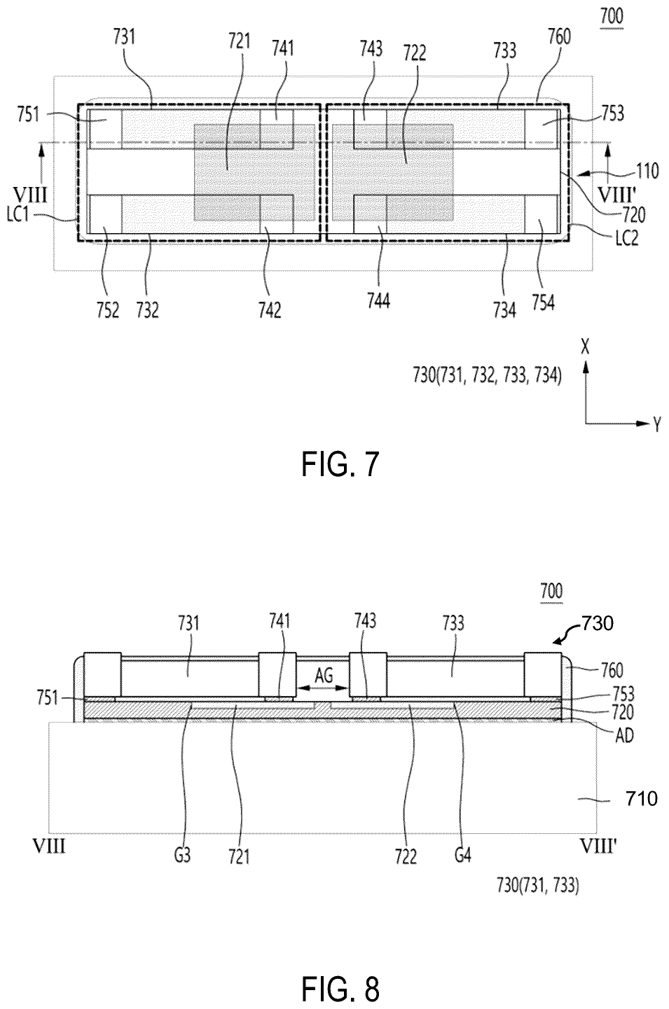

FIG. 7 is a schematic plan view of a loopback circuit package according to an embodiment of the present disclosure, and FIG. 8 is a schematic cross-sectional view of the loopback circuit package taken along line VIII-VIII′ of FIG. 7.

Referring to FIGS. 7 and 8, a loopback circuit package (700) may include a semiconductor substrate (720) arranged on a package substrate (710) and an inductor layer (730) arranged on the semiconductor substrate (720). Detailed descriptions regarding the package substrate (710), semiconductor substrate (720), and inductor layer (730) are similar to those provided for the embodiment of the loopback circuit package (100) in FIGS. 2 to 4; therefore, redundant descriptions may be omitted for the interest of brevity.

On the package substrate (710), a first LC section (LC1) and a second LC section (LC2) may be arranged at a distance from each other. The first LC section (LC1) may include the first capacitor (721), the first inductor (731), the second inductor (732), the first signal bump (741), the second signal bump (742), the first dummy bump (751), and the second dummy bump (752). The second LC section (LC2) may include the second capacitor (722), the third inductor (733), the fourth inductor (734), the third signal bump (743), the fourth signal bump (744), the third dummy bump (753), and the fourth dummy bump (754). The first signal bump (741) to the fourth signal bump (744) may be referred to as signal transmission portions, while the first dummy bump (751) to the fourth dummy bump (754) may be referred to as shock mitigation portions.

The semiconductor substrate (720) is arranged on the package substrate (710). In other words, the semiconductor substrate (720) may be positioned between the package substrate (710) and the inductor layer (730). The area or size of the semiconductor substrate (720) may be smaller than or equal to the area or size of the package substrate (710). The package substrate (710) and the semiconductor substrate (720) may be bonded with an adhesive material or adhesive layer (AD). The adhesive material may be applied to the underside of the semiconductor substrate (720) to form the adhesive layer (AD). The semiconductor substrate (720) may be composed of silicon, more specifically, P-type or N-type or undoped silicon.

In upper portions of the semiconductor substrate (720), the third trench (or third recess) (G3) and the fourth trench (or fourth recess) (G4) may be formed. The third trench (G3) can be formed in areas at least partially overlapping with the first inductor (731) and the second inductor (732) that are arranged on the upper surface of the semiconductor substrate (720). Similarly, the fourth trench (G4) can be formed in areas at least partially overlapping with the third inductor (733) and the fourth inductor (734) that are arranged on the upper surface of the semiconductor substrate (720).

The first capacitor (721) may be formed in the third trench (or third recess) (G3), while the second capacitor (722) may be formed in the fourth trench (or fourth recess) (G4). The first capacitor (721) can be arranged to overlap at least partially with the first inductor (731) and the second inductor (732) that are positioned on the upper surface of the semiconductor substrate (720). Similarly, the second capacitor (722) can be arranged to overlap at least partially with the third inductor (733) and the fourth inductor (734) that are positioned on the upper surface of the semiconductor substrate (720). Thus, the loopback circuit package (700) according to the embodiment of FIGS. 7 and 8 can significantly reduce its overall thickness by etching some portions of the semiconductor substrate (720) to allow the first capacitor (721) to be positioned in the third trench (G3) and the second capacitor (722) to be positioned in the fourth trench (G4), compared to a conventional loopback circuit package.

The first capacitor (721) and the second capacitor (722) can have substantially the same structure. Specifically, each of the first capacitor (721) and the second capacitor (722) can be a trench-type capacitor capable of providing sufficient capacitance, such as the deep trench capacitor described in FIG. 5.

On the upper surface of each of the first capacitor (721) and the second capacitor (722), the first bump (741), the second bump (742), the third bump (743), and the fourth bump (744) are arranged.

The first bump (741) is positioned between the first capacitor (721) and the first inductor (731) to electrically connect them. The first bump (741) is in contact with the first capacitor (721) and the first inductor (731) to transmit various signals to the first capacitor (721) and the first inductor (731). Specifically, the first bump (741) can function as a sink bump or a source bump, transmitting sink signals or source signals to the first capacitor (721) and the first inductor (731).

The second bump (742) is positioned between the first capacitor (721) and the second inductor (732) to electrically connect them. The second bump (742) is in contact with the first capacitor (721) and the second inductor (732) to transmit various signals to the first capacitor (721) and the second inductor (732). Specifically, the second bump (742) can function as a sink bump or a source bump, transmitting sink signals or source signals to the first capacitor (721) and the second inductor (732).

The first bump (741) and the second bump (742) can transmit different signals. Specifically, if the first bump (741) transmits source signals, then the second bump (742) can transmit sink signals.

The third bump (743) is positioned between the second capacitor (722) and the third inductor (733) to electrically connect them. The third bump (743) is in contact with the second capacitor (722) and the third inductor (733) to transmit various signals to the second capacitor (722) and the third inductor (733). Specifically, the third bump (743) can function as a sink bump or a source bump, transmitting sink signals or source signals to the second capacitor (722) and the third inductor (733).

The fourth bump (744) is positioned between the second capacitor (722) and the fourth inductor (734) to electrically connect them. The fourth bump (744) is in contact with the second capacitor (722) and the fourth inductor (734) to transmit various signals to the second capacitor (722) and the fourth inductor (734). Specifically, the fourth bump (744) can function as a sink bump or a source bump, transmitting sink signals or source signals to the second capacitor (722) and the fourth inductor (734).

The third bump (743) and the fourth bump (744) can transmit different signals. Specifically, if the third bump (743) transmits source signals, then the fourth bump (744) can transmit sink signals.

The first bump (741), second bump (742), third bump (743), and fourth bump (744) can be made of conductive materials. For example, they can be composed of at least one conductive material such as copper (Cu), nickel (Ni), gold (Au), tin (Sn), and silver (Ag), or a combination thereof.

In areas where the third trench (G3) and fourth trench (G4) are not positioned on the semiconductor substrate (720), the first dummy bump (751), the second dummy bump (752), the third dummy bump (753), and the fourth dummy bump (754) can be placed. The first dummy bump (751) and the second dummy bump (752) can be positioned on the upper surface of the semiconductor substrate (720) where the third trench (G3) is not formed, while the third dummy bump (753) and the fourth dummy bump (754) can be positioned on the upper surface of the semiconductor substrate (720) where the fourth trench (G4) is not formed.

The first dummy bump (751) can be positioned between the upper surface of the semiconductor substrate (720) and the first inductor (731), contacting both of the upper surface of the semiconductor substrate (720) and the lower surface of the first inductor (731). Similarly, the second dummy bump (752) can be placed between the upper surface of the semiconductor substrate (720) and the second inductor (732), contacting both of the upper surface of the semiconductor substrate (720) and the lower surface of the second inductor (732). Therefore, the first dummy bump (751) and second dummy bump (752) ensure stable placement between the semiconductor substrate (720) including the first capacitor (721), the first inductor (731), and the second inductor (732) even under external impacts.

The third dummy bump (753) can be positioned between the upper surface of the semiconductor substrate (720) and the third inductor (733), contacting both of the upper surface of the semiconductor substrate (720) and the lower surface of the third inductor (733). Similarly, the fourth dummy bump (754) can be placed between the upper surface of the semiconductor substrate (720) and the fourth inductor (734), contacting both of the upper surface of the semiconductor substrate (720) and the lower surface of the fourth inductor (734). Therefore, the third dummy bump (753) and fourth dummy bump (754) ensure stable placement between the semiconductor substrate (720) including the second capacitor (722), the third inductor (733), and the fourth inductor (734) even under external impacts.

The first inductor (731) of the first LC section (LC1) and the third inductor (733) of the second LC section (LC2) can be spaced apart, with an air gap (AG) or a molding layer (760) between them. Through this air gap (AG) or molding layer (760), the loopback circuit package (700) can clearly separate the first LC section (LC1) and the second LC section (LC2). Furthermore, with the clear separation of the first LC section (LC1) and the second LC section (LC2) through the air gap (AG) or molding layer (760), the integration density can be increased by including two independent LC circuits within a single loopback circuit package.

One end of the first inductor (731) can be positioned in an area overlapping with the first capacitor (721) and the first signal bump (741) that are located on the lower surface of the first inductor (731), while the other end of the first inductor (731) can be positioned in an area overlapping with the upper surface of the semiconductor substrate (720) and the first dummy bump (751).

Similarly, one end of the second inductor (732) can be placed in an area overlapping with the first capacitor (721) and the second signal bump (742) that are located on the lower surface of the second inductor (732), while the other end of the second inductor (732) can be positioned in an area overlapping with the upper surface of the semiconductor substrate (720) and the second dummy bump (752).

One end of the third inductor (733) can be positioned in an area overlapping with the second capacitor (722) and the third signal bump (743) that are located on the lower surface of the third inductor (733), while the other end of the third inductor (733) can be placed in an area overlapping with the upper surface of the semiconductor substrate (720) and the third dummy bump (753).

Similarly, one end of the fourth inductor (734) can be placed in an area overlapping with the second capacitor (722) and the fourth signal bump (744) that are located on the lower surface of the fourth inductor (734), while the other end of the fourth inductor (734) can be positioned in an area overlapping with the upper surface of the semiconductor substrate (720) and the fourth dummy bump (754). These inductors (731) through (734) could be, for example, magnetic inductors or magnetic core inductors.

The mold layer (760) is placed to cover (e.g., encapsulate or encase) the semiconductor substrate (720) located on the upper surface of the package substrate (710) and the inductor layer (730) located on the upper surface of the semiconductor substrate (720). The mold layer (760) can be formed to wrap around substantially the entire sides of the semiconductor substrate (720) and the inductor layer (730). It could be made of materials such as epoxy resin or various other polymers and materials.

The loopback circuit package (700) according to an embodiment of the present invention, as illustrated in FIGS. 7 and 8, includes four dummy bumps (751, 752, 753, 754) placed between the capacitors (721, 722) arranged on the semiconductor substrate (720) and the inductor (730). Consequently, the loopback circuit package (700) can reduce weight and manufacturing costs by including a relatively few number of dummy bumps. Moreover, the semiconductor substrate (720) may be directly attached to the package substrate (710) through an adhesive layer (AD) made of adhesive material, thereby obviating the usage of separate bonding pads for bonding the semiconductor substrate (720) to the package substrate (710). Thus, the thickness of the loopback circuit package (700) can be reduced by the thickness of the bonding pads, resulting in an overall thinner package.

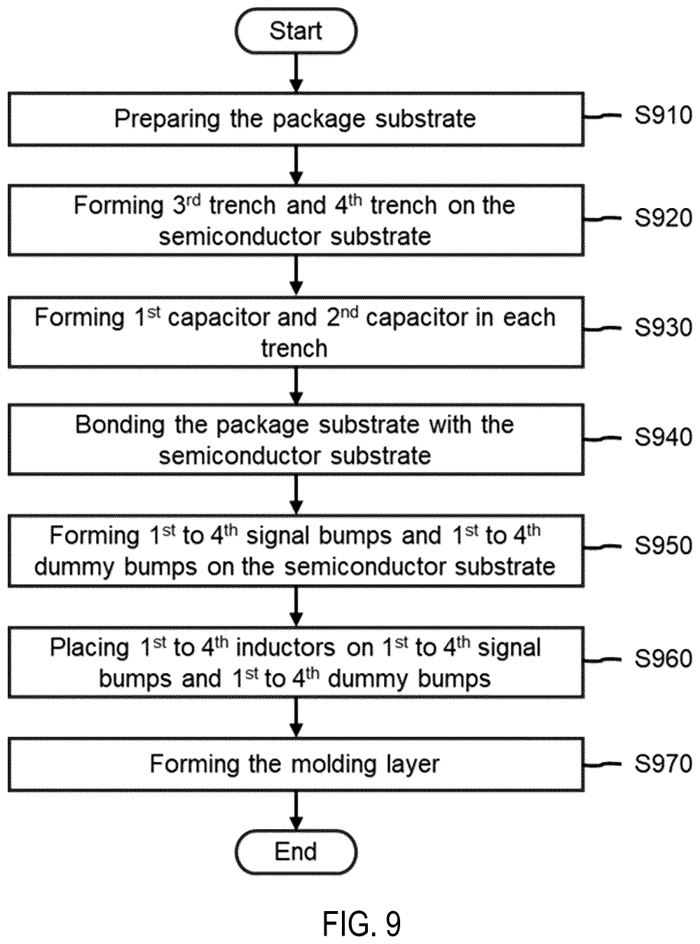

FIG. 9 is a flowchart illustrating a method for manufacturing a loopback circuit package (e.g., the loopback circuit package (700) in FIGS. 7 and 8) according to an embodiment of the present disclosure.

Referring to FIG. 9, a loopback circuit package (700) is first prepared by preparing the package substrate (710) (S910).

Subsequently, after preparing the semiconductor substrate (720), the third trench (or the third recess) (G3) and the fourth trench (or the second recess) (G4) (S920) formed on the semiconductor substrate (720), and then the first capacitor (721) and the second capacitor (722) are formed in the third and fourth trenches (G3 and G4), respectively (S930). For example, multiple trenches may be formed in each of the trenches (G3 and G4), and then the first capacitor pattern (131a) and the second capacitor pattern are formed along the multiple trenches of the third and fourth trenches (G3 and G4), respectively, resulting in the formation of the first capacitor (721) and the second capacitor (722).

Subsequently, after applying adhesive material (AD) to the bottom surface of the semiconductor substrate (720) or the top surface of the package substrate (710), the semiconductor substrate (720) and the package substrate (710) are bonded together (S940).

Then, the first to fourth signal bumps (741, 742, 743, 744) are arranged to overlap with the first capacitor (721) and the second capacitor (722) on the semiconductor substrate (720), and the first to fourth dummy bumps (751, 752, 753, 754) are arranged on the top surface of the semiconductor substrate (720) where the third and fourth trenches (G3 and G4) are not formed (S950).

Afterwards, the first to fourth inductors (731, 732, 733, 734) can be placed on top of the first to fourth signal bumps (741, 742, 743, 744) and the first to fourth dummy bumps (751, 752, 753, 754) (S960). Specifically, the first inductor (731) is placed on top of the first signal bump (741) and the first dummy bump (751) to overlap with them, the second inductor (732) is placed on top of the second signal bump (742) and the second dummy bump (752) to overlap with them, the third inductor (733) is placed on top of the third signal bump (743) and the third dummy bump (753) to overlap with them, and the fourth inductor (734) is placed on top of the fourth signal bump (744) and the fourth dummy bump (754) to overlap with them.

Subsequently, at S970, the manufacturing process of the loopback circuit package (700) further include forming a mold layer (760) to cover (e.g., encapsulate) substantially the entire sides of the semiconductor substrate (720) and substantially the entire sides and a top surface the inductor layer (730) on the package substrate (710), and removing the lower package substrate (710) to complete the manufacturing process. Specifically, after the mold layer (760) has been formed, the package substrate (710) may be removed from the remaining structure including the inductor layer (730) and the semiconductor substrate (720) to complete the manufacturing process of the loopback circuit package (700).

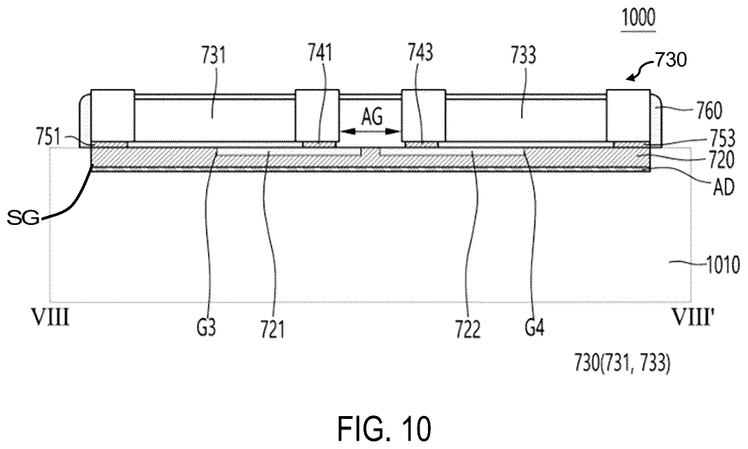

FIG. 10 is a schematic cross-sectional view of a loopback circuit package according to an embodiment of the present disclosure. More specifically, FIG. 10 may be a cross-sectional view according to line VII-VII′ of FIG. 7. Therefore, descriptions similar to those described above with reference to the embodiment of FIG. 8 may be omitted for the interest of brevity.

Referring to FIG. 10, the loopback circuit package (1000) according to an embodiment of the present disclosure may include a package substrate (1010), a semiconductor substrate (720), and an inductor layer (730). It may further include the first to fourth signal bumps (741, 742, 743, 744) and the first to fourth dummy bumps (751, 752, 753, 754) placed between the semiconductor substrate (720) and the inductor layer (730).

The package substrate (1010) may have one or more substrate grooves (SG) with a size and a thickness corresponding to the size and thickness of the semiconductor substrate (720), respectively. For example, the semiconductor substrate (720) may be a single integrated substrate and the package substrate (1010) may be disposed in a single continuous substrate groove (SG) of the semiconductor substrate 720. In an embodiment, the substrate grooves (SG) of the package substrate 1010 may be formed on an upper surface of the package substrate (1010), such that a size and a thickness of the substrate grooves (SG) may be sufficiently large to accommodate the semiconductor substrate (720) therein. For example, the substrate grooves (SG) may have a bottom surface with an area that is substantially equal to or greater than an area of a main surface (e.g., an upper or lower surface) of the semiconductor substrate (720) and a thickness that is substantially equal to or greater than a thickness of the semiconductor substrate (720). The semiconductor substrate (720) with the first capacitor (721) and the second capacitor (722) formed therein can be placed in the substrate grooves (SG). The semiconductor substrate (720) can be adhered to the package substrate (1010) by an adhesive layer (AD) made of adhesive material in the substrate grooves (SG).

Thus, the loopback circuit package (1000) according to the embodiment of FIG. 10, substrate grooves (SG) are formed in the package substrate (1010). The semiconductor substrate (720) containing the first capacitor (721) and the second capacitor (722) is placed in the substrate grooves (SG), followed by forming the inductor layer (730) on the semiconductor substrate (720), allowing the capacitors (721, 722) and the semiconductor substrate (720) to be arranged within the package substrate (1010). For example, a top surface of the semiconductor substrate (720) may be substantially coplanar with a top surface of the package substrate (1010). Since the semiconductor substrate (720) including the capacitors 721 and 722 is formed within the package substrate 1010, an overall thickness of the loopback circuit package (1000) may be further reduced by the thickness of the semiconductor substrate (720), compared to an overall thickness of the loopback circuit package 700 in FIG. 8.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

What is claimed is:

1. A loopback circuit package comprising:
an inductor layer including a first inductor, a second inductor, a third inductor, and a fourth inductor; and
a semiconductor substrate including a first capacitor electrically connected to the first inductor and the second inductor and a second capacitor electrically connected to the third inductor and the fourth inductor,
wherein the first capacitor and the second capacitor are disposed in a first recess and a second recess of the semiconductor substrate, respectively.

2. The loopback circuit package of claim 1, further comprising:
first signal transmission portions electrically connected to the first inductor, the second inductor, and the first capacitor;
second signal transmission portions electrically connected to the third inductor, the fourth inductor, and the second capacitor; and
shock mitigation portions arranged between the semiconductor substrate and the first inductor, the second inductor, the third inductor, and the fourth inductor.

3. The loopback circuit package of claim 2, wherein:
a first LC section includes the first inductor, the second inductor, and the first capacitor; and
a second LC section includes the third inductor, the fourth inductor, and the second capacitor.

4. The loopback circuit package of claim 3, wherein the first inductor of the first LC section and the third inductor of the second LC section are spaced apart from each other, or the second inductor of the first LC section and the fourth inductor of the second LC section are spaced apart from each other, or both, and
wherein an air gap or a molding layer is formed between the first inductor the third inductor, or between the second inductor and the fourth inductor, or both.

5. The loopback circuit package of claim 4, further comprising a package substrate,
wherein the inductor layer is disposed on an upper surface of the package substrate, the semiconductor substrate is disposed on an upper surface of the inductor layer, and the first and second signal transmission portions and the shock mitigation portions are disposed between the inductor layer and the semiconductor substrate.

6. The loopback circuit package of claim 5, wherein the first recess and the second recess are formed on a lower surface of the semiconductor substrate.

7. The loopback circuit package of claim 5, wherein the first signal transmission portions comprise:
a first signal pad configured to transmit a signal and disposed to contact the first inductor and the first capacitor; and
a second signal pad configured to transmit a signal and disposed to contact the second inductor and the first capacitor, and
wherein the second signal transmission portions comprise:
a third signal pad configured to transmit a signal and disposed to contact the third inductor and the second capacitor; and
a fourth signal pad configured to transmit a signal and disposed to contact the fourth inductor and the second capacitor.

8. The loopback circuit package of claim 5, wherein the shock mitigation portions comprise:
a first dummy pad disposed to contact the first inductor and the semiconductor substrate;
a second dummy pad disposed to contact the second inductor and the semiconductor substrate;
a third dummy pad disposed to contact the third inductor and the semiconductor substrate; and
a fourth dummy pad disposed to contact the fourth inductor and the semiconductor substrate.

9. The loopback circuit package of claim 7, wherein the first signal pad, the second signal pad, the third signal pad, and the fourth signal pad are further configured to reduce impedance mismatch between the first inductor and the first capacitor, between the second inductor and the first capacitor, between the third inductor and the second capacitor, and between the fourth inductor and the second capacitor, respectively.

10. The loopback circuit package of claim 5, further comprising connection pads arranged between the package substrate and the inductor layer.

11. The loopback circuit package of claim 4, wherein the inductor layer is disposed on an upper surface of the semiconductor substrate, and the first and second signal transmission portions and the shock mitigation portions are arranged between the inductor layer and the semiconductor substrate.

12. The loopback circuit package of claim 11, wherein the first recess and the second recess are formed on an upper surface of the semiconductor substrate.

13. The loopback circuit package of claim 11, wherein the first signal transmission portions comprise:
a first signal bump disposed to contact the first inductor and the first capacitor to transmit a signal; and
a second signal bump disposed to contact the second inductor and the first capacitor to transmit a signal, and
wherein the second signal transmission portions comprise:
a third signal bump disposed to contact the third inductor and the second capacitor to transmit a signal; and
a fourth signal bump disposed to contact the fourth inductor and the second capacitor to transmit a signal.

14. The loopback circuit package of claim 11, the shock mitigation portions comprise:
a first dummy bump disposed to contact the first inductor and the semiconductor substrate;
a second dummy bump disposed to contact the second inductor and the semiconductor substrate;
a third dummy bump disposed to contact the third inductor and the semiconductor substrate; and
a fourth dummy bump disposed to contact the fourth inductor and the semiconductor substrate.

15. The loopback circuit package of claim 4, further comprising a package substrate on which the inductor layer is disposed,
wherein one or more substrate grooves are formed on an upper surface of the package substrate, and the substrate grooves have a size and a thickness corresponding to those of the semiconductor substrate.

16. The loopback circuit package of claim 15, wherein the semiconductor substrate is placed in the substrate grooves of the package substrate, and the inductor layer is disposed on an upper surface of the semiconductor substrate, and the first and second signal transmission portions and the shock mitigation portions are arranged between the inductor layer and the semiconductor substrate.

17. A method of manufacturing a loopback circuit package, comprising:
providing a package substrate;
providing an inductor layer on the package substrate, the inductor layer including a first inductor, a second inductor, a third inductor, and a fourth inductor; and
providing a semiconductor substrate on the package substrate, the semiconductor substrate including a first capacitor electrically connected to the first inductor and the second inductor and a second capacitor electrically connected to the third inductor and the fourth inductor,
wherein the first capacitor and the second capacitor are disposed in a first recess and a second recess of the semiconductor substrate, respectively, the first recess and the second recess being formed by etching the semiconductor substrate.

18. The method of claim 17, wherein the semiconductor substrate is directly attached to the package substrate using an adhesive layer.

19. The method of claim 17, further comprising removing the package substrate from a structure including the inductor layer and the semiconductor substrate.
